(19) United States
(12) Patent Application Publication
(10) Pub. No.: US 2011/0110544 A1
(43) Pub. Date: May 12, 2011

(54) METHOD OF COATING A HEARING AID COMPONENT AND A HEARING AID COMPRISING A COATED COMPONENT

(75) Inventors: Jorn Eiler VESTERGAARD, Helsinge (DK); Jorgen Mejner OLSEN, Hillerod (DK); Kenneth Brian HAUGSHOJ, Taastrup (DK); Leif Hojslet CHRISTENSEN, Roskilde (DK); Tina Ahlberg LARSEN, Birkerod (DK)

(73) Assignee: Widex A/S, Lynge (DK)

(21) Appl. No.: 13/007,011

(22) Filed: Jan. 14, 2011

Related U.S. Application Data
(63) Continuation-in-part of application No. PCT/DK2008/050201, filed on Aug. 14, 2008.

(51) Int. Cl. H04R 25/00; C23C 16/02; C23C 16/30

(52) U.S. Cl. 381/312; 427/255.7

(57) ABSTRACT

A method for coating of a hearing aid said method comprising the deposition of an adhesion layer that does not develop corrosive reaction products. The method comprises applying an organometallic compound to the surface of the hearing aid component using vapour phase deposition, inducing a reaction to convert it to a metal oxide, then applying a silane molecule to the surface, and inducing a reaction between the applied silane molecule and the metal oxide. The invention also relates to a hearing aid comprising a component for a hearing aid provided with a hydrophobic coating comprising a layer of aluminium oxide, and a coating for a hearing aid component. The coating is produced in a system (701) for vapour phase deposition of precursors.

### RELATED APPLICATIONS

The present application is a continuation-in-part of application no. PCT/DK2008050201 filed on Aug. 14, 2008 and published as WO-A1-2010017816, the contents of which are incorporated herein by reference.

### BACKGROUND OF THE INVENTION

1. Field of the Invention

The present invention relates to a method of coating a hearing aid component. The invention further relates to a hearing aid comprising a coated component. The invention, still more specifically, relates to a method for coating a hearing aid component, where the coatings are produced in a process comprising vapour phase deposition of a metal oxide layer followed by a silane layer. The invention also relates to hearing aid components with a coating and hearing aids comprising such components. The invention further relates to a coating for a hearing aid component.

2. The Prior Art

Hearing aids generally include a range of components such as housing, internal electronic circuitry, transducers, sound conduits, ear pieces, switches, buttons, connectors and various accessories such as earwax guards, mechanical adaptors and FM units. More specifically the housing may be made out of shells and may further comprise battery lid, battery compartment and protective microphone grids. The internal electronic circuitry and the transducers may be at least partly covered by sleeve-like gaskets providing sealing connection as well as resilient suspension, and the transducers may further include additional protective screens in the acoustical path.

In-the-Ear (ITE) and completely-in-canal (CIC) hearing aids generally comprise a shell, which anatomically fits the relevant part of the user's ear canal. A receiver is placed in the shell in communication with an acoustic outlet port arranged at the proximal end, i.e. the end of the shell adapted for being situated in the ear canal close to the tympanic membrane. The distal end of the shell, i.e. the opposite end, intended to be oriented towards the surroundings, is closed by a faceplate subassembly, connected to the receiver by leads. In one design, the faceplate subassembly incorporates a microphone, electronics, a battery compartment and a hinged lid. The microphone communicates with the exterior through a port, which may be covered by a grid.

Whereas an ITE hearing aid may be regarded as an earpiece integrating all parts of a hearing aid, a Behind-The-Ear (BTE) hearing aid comprises a housing adapted for resting over the pinna of the user and an ear piece adapted for insertion into the ear canal of the user and serving to convey the desired acoustic output into the ear canal. The earpiece is connected to the BTE housing by a sound conduit or, in case it houses the receiver, by electric leads. In either case it has an output port for conveying the sound output.

During normal use, a hearing aid is exposed to environmental factors such as wear, moisture, sweat, earwax, fungi, bacteria, dirt and water. Some of those factors may have a corroding influence; others may cause development of an undesired biofilm or of an otherwise irregular surface patina. Corrosion may be controlled by the selection of durable materials. However the environmental factors may over time create an unsightly appearance.

It is often desirable to apply a coating onto a hearing aid surface. This may be a hydrophobic coating in order to improve moisture resistance and hereby protect the hearing aid electronics. It could also be a scratch resistant coating in order to maintain the hearing aid appearance or it could be some other form of coating.

WO2008/025355 describes a filter for a hearing aid serving as an earwax guard. Such filters may be treated in a coating process involving an initial plasma treatment to activate the surface of the filter element by introducing superficial hydroxyl groups before coating in a vapour deposition method utilising silane chemistry. In order to make the exterior surface hydrophobic, perfluoroalkylsilanes or alkylsilanes may be used. The plasma treatment is particularly important for non-metallic, polymeric substrates, which require that an adhesion layer is applied prior to the silane coating. The substrate may further be microstructured prior to any coating so that the final, coated filter will be provided with a superhydrophobic surface.

PCT/DK2007/000002, published as WO2008/080597, discloses components for hearing aids the surfaces of which are made hydrophobic or superhydrophobic in a process involving plasma treatment followed by attachment of a self-assembled monolayer of a perfluoroalkylsilane or an alkylsilane from a vapour phase deposition. The surfaces may be microstructured prior to the silane coating, and in order to provide superhydrophobicity a microstructuring step will be necessary before the coating.

WO2007/054649 describes a product with a superhydrophobic or superhydrophilic coating. This product is created by initially applying an intermediary layer of nanometer-scale thickness onto a substrate, such as polymers or glass, using a vapour deposition method. Subsequently the intermediary layer is provided with nanoscale roughness before applying a second layer to provide desired physical properties, such as superhydrophobicity. These superhydrophobic coatings may be used to prevent condensation of water on e.g. glasses, or to make a surface highly slippery for liquids. As an example, a silicon-layer of 50-300 nm thickness can be created on a polymethyl methacrylate (PMMA) substrate by depositing silane gas on the surface using so-called plasma enhanced chemical vapour deposition. This layer is then exposed to a plasma treatment to create nanoscale engravings on the surface before treating the now roughened surface with dimethyl tetrasiloxane in a vapour deposition step. The product thus manufactured should now be provided with a continuous film with a surface making the substrate superhydrophobic. The method is said to be useful to both heat-labile materials, such as thermoplastic polymers, and more stable substrates. However, considering the chemistries involved in the application of the intermediary silicon-layer to the substrate it is unclear if this method yields a coating of sufficient durability.

US2005/0186731 describes the formation of an oxide layer on a substrate, such as a silicon wafer. Specifically, atomic layer deposition (ALD) is employed to deposit an oxide monolayer from a metalloorganic precursor, such as trimethyl aluminium (TMA), which will result in the formation of aluminium oxide. For the reaction to take place the method of US2005/0186731 relies on the use of ozone gas at elevated temperatures together with the metalloorganic precursor. The method of US2005/0186731 is suited for use in the manufacturing of semiconductors for integrated circuits, and no information is given regarding the hydrophobicity or hydrophilicity of the created surfaces.

US2004/0221798 relates to a method to grow a thin film on a substrate by ALD. In this process a gaseous compound of a metal or semiconductor element is deposited and reacted with a gaseous second reactant. Depending on the choice of reactants the formed thin film may be metallic or an oxide or other compound of a metal. One example is the formation of aluminium oxide by depositing TMA prior to reacting this with water. The described method may also be employed in a plurality of coating cycles though the exact nature of such a multilayer coating is not described. The method of US2004/0221798 is not explicitly limited to a specific field though the method appears to be intended for use in the manufacture of semiconductor components, since the electrical properties of the created coatings appear to be of importance. The document likewise does not specify the exact composition of the substrate though it is mentioned that the coatings may be formed on a metallic substrate or an oxide of a metal. With an emphasis on electrical properties other physical properties, such as hydrophobicity, hydrophilicity or mechanical properties of the coatings are not mentioned, and it is furthermore unclear what effect the formed coating has on the durability of the final product.

WO2005/121397 concerns methods to create multilayered coatings employing a vapour deposition principle entitled “molecular vapour deposition” with the aim to control the layer thickness, the mechanical and surface properties as well as to provide functionality on a nanometer scale. It was found that it is possible to convert a hydrophilic-like substrate surface to a hydrophobic surface by application of an oxide-based layer to a given substrate, followed by application of an organic-based layer over the oxide-based layer, where the organic-based layer provides hydrophobic surface functional groups on the end of the organic molecule which do not react with the oxide-based layer. By controlling the process parameters it was further found that the density of film coverage over the substrate surface and structural composition could be controlled, enabling the formation of very smooth films. For producing intermediary oxide layers, the methods of WO2005/121397 generally rely on halogenated silanes, such as chlorosilanes, chlorosiloxanes, fluorosilanes, and fluorosiloxanes, for use as precursors. Upon reaction these chemicals will produce halogen hydrides, e.g. HCl, as a by-product. The described multilayer coatings produced are provided with superficial functionalities by using various perfluorosilanes or alkylsilanes in the final coating step to create hydrophobic surfaces. These compounds are typically in the form of a corresponding di- or trichlorosilane or methoxysilanes. The provided superficial functionalities may also be of a reactive nature comprising moieties such as 3-aminopropyl moieties or 3-glycidoxy moieties. The methods of WO2005/121397 are suited for different types of substrates, such as stainless steel, glass, polystyrene, acrylic or silicon wafers. However, bearing in mind that the reaction of the chlorosilanes typically used will produce small amounts of HCl as a by-product during the coating it will be clear that the reaction performed may be harmful to the substrate due to the corrosive nature of HCl.

On this background it is a feature of the present invention to provide a coating with improved adhesion and mechanical properties and for overcoming problems related to formation of corrosive byproducts and other problems.

This feature is achieved with a coating produced in a process, which is generally free from formation of corrosive reaction products. Furthermore, the adhesion properties of the coating and the durability of the paint or metallisation layer are improved.

### SUMMARY OF THE INVENTION

The present invention, in a first aspect, provides a method for coating a hearing aid component, which method comprises the steps of:
a) providing a hearing aid component;
b) applying an organometallic compound to the surface of the hearing aid component using vapour phase deposition;
c) inducing a reaction involving the applied organometallic compound to convert it to a metal oxide layer;
d) applying a silane molecule to the metal oxide on the surface of the hearing aid component using vapour phase deposition; and
e) inducing a reaction between the applied silane molecule and the metal oxide to form covalent links between the silane molecule and the metal oxide or to covalently link neighbouring applied silane molecules.

The hearing aid component may be any component used in the construction of a hearing aid, or it may be an assembly of several such components. Organometallic compounds are well-known within the art, and in on embodiment the organometallic compound is trimethyl aluminium (TMA or Al(CH₃)₃). Any vapour phase deposition method is suited to apply the organometallic compound to the surface of the hearing aid component, but the organometallic compound is preferably applied using molecular vapour deposition and/or atomic layer deposition. During the vapour phase deposition the metalloorganic compound will typically be applied at a pressure from 0.01-10 Torr, although for certain applications the pressure may appropriately be even lower than 0.01 Torr. The application temperature may be from ambient temperature up to around 100° C., or even higher depending on the nature of the substrate and the deposited compound. The application time will commonly be less than around one minute, typically 0.5-10 s.

Upon vapour phase deposition of the organometallic compound or the silane molecule in the respective steps, the compound or molecule will adsorb physically to the surface. The adsorption will preferably take the form of a monolayer. After formation of the monolayer the conditions may be modified to induce a reaction involving the adsorbed compound or molecule. Alternatively, compounds or molecules may be adsorbed which will not require a change in conditions to induce a reaction so that the reaction can be said to occur spontaneously. The induction of a reaction may be initiated by the application of a chemical, which will react with the adsorbed entities so as to induce the formation of a covalent bond between the adsorbed entities and atoms on the surface and/or between neighbouring adsorbed entities. When the organometallic compound is TMA the reaction may be induced by the application of water molecules to the surface, although other compounds, such as hydrogen peroxide (H₂O₂), oxygen (O₂), ozone (O₃), may also be employed. Induction with water molecules is preferred, and the water molecules are preferably applied from a gaseous phase.

In one embodiment the steps b) and c) to respectively apply an organometallic compound and subsequently inducing a reaction to form a metal oxide are repeated. By repeating these steps it is possible to sequentially build layers of metal oxide and thereby provide a desired thickness of the metal oxide layer. In an embodiment the thickness of the layer is between 2-20 nm. In another embodiment the thickness of the layer is between 5-10 nm.

The organometallic compounds applied in the steps need not be identical, and the layering can follow any desired pattern. For example, compounds based on two different metals may be used to create a layer alternating between the oxides of the metals, which alternating layers may be of the same or different thicknesses. The organometallic compounds may be selected such that the resulting coating of metal oxides will contain layers of aluminium oxide and silicon oxide; the layers of aluminium oxide and silicon oxide need not be of the same thickness, and the invention is not particularly limited to a specific number of layers. It is also within the scope of the invention to build layers of metal oxide containing more than two different metals; in addition to TMA and silanes, relevant organometallic compounds may be diethyl zinc to produce a zinc oxide layer or titanium alkoxides (Ti(OR)₄) to produce a titanium oxide layer.

Layers of silicon oxide are preferably provided by applying 1,2-bis(trichlorosilyl)ethane to the surface of the hearing aid component using vapour phase deposition and inducing a reaction involving the applied 1,2-bis(trichlorosilyl)ethane to convert it to silicon oxide. 1,2-bis(trichlorosilyl)ethane will typically be applied to a metal oxide surface formed in step c), and following the conversion to silicon oxide another layer of metal oxide may be formed by repeating steps b) and c). In a multilayering process involving multiple layers of metal oxide several such silicon oxide layers may also be formed between the metal oxide layers.

The coating of the hearing aid component is preferably of a nature to make the final coating hydrophobic or superhydrophobic. This may be obtained using a silane molecule comprising a perfluoroalkyl moiety or a fluoroalkyl moiety. In an embodiment the perfluoro-comprising silane molecule is perfluorodecyl trichlorosilane (FDTS). Other relevant fluoroalkyl- or perfluoroalkyl compounds may, for example, be perfluorooctyl trichlorosilane (FOTS) or trichlorosilanes with octyl- or decyl groups carrying any number of fluorine atoms up to the maximum possible. Hydrophobicity or superhydrophobicity may also be provided using a silane molecule with alkyl chains without fluorine atoms.

The silane molecule may also be applied using any vapour phase deposition method. Preferred methods for application of the silane molecule are molecular vapour deposition and atomic layer deposition.

Prior to the application of an organometallic compound and formation of the metal oxide, the hearing aid component may be treated to microstructure the surface. Thus, the process of the invention may further comprise the step of microstructuring the exterior surface of the hearing aid component prior to applying the organometallic compound. Any procedure capable of providing a microstructure to the surface is relevant for the present invention. Laser processing of the surface using lasers such as CO₂ lasers, excimer lasers, diode lasers, fibre lasers, solid state lasers, such as Nd:YAG, picosecond lasers and femtosecond lasers is especially relevant. Other processes, such as microinjection moulding, or those used in the fabrication of micro/nano-electronics or micro/nano-electromechanical systems as well as other etching or electrochemical processes may also be applied.

The component for a hearing aid may also be provided with a number of through-going pores, the largest cross-sectional dimension of each of the pores being smaller than 200 μm prior to applying the coating. The pores will typically have cross-sectional dimensions ranging from 100-200 μm, although other sizes are also contemplated. Thus, the method of the invention may also comprise the step of perforating the hearing aid component with a number of such pores. This perforation may be provided using any suited method, for example stamping holes through the component or component substrate. The perforation may also be provided using laser ablation with such lasers as CO₂ lasers, excimer lasers, diode lasers, fibre lasers, solid state lasers, such as Nd:YAG, picosecond lasers and femtosecond lasers. Microinjection moulding of substrates may likewise be relevant.

Depending on the nature of the surface of the hearing aid component it may be advantageous to apply a treatment with an oxygen plasma prior to application of the organometallic compound. Treatment with an oxygen plasma will introduce hydroxyl groups into the surface, which may then be reacted with the organometallic compound to form a metal oxide layer covalently linked to the surface. Treatment with an oxygen plasma is preferred when the outermost layer of the surface of the hearing aid component comprises a polymeric material, though it may also be included for producing a coating on a surface with an outer layer of metal atoms or a metal oxide. Other types of plasma than oxygen plasma may also be employed.

The invention, in a second aspect, provides a hearing aid, comprising a component provided with a hydrophobic coating comprising a layer of aluminium oxide.

Such a coating may be provided by the method according to the invention. The surface of the component may be essentially entirely coated with the coating or it may be intentionally partially coated with the coating. A component with a coating of the invention may comprise an outer surface of a polymeric material. Any polymeric material is appropriate, although in certain embodiments materials such as polyoxymethylene (POM), acrylonitrile butadiene styrene (ABS), polycarbonate (PC) or a blend of ABS and PC known as ABS/PC are preferred. POM is also known as Acetal plastic. Further relevant types of polymeric materials are cellulosepropionate (CAP/CP), methyl methacrylate acrylonitrile butadiene styrene (MABS), polyamide (PA), thermoplastic polyester (PBT) and polymethyl methacrylate (PMMA). A component with a metallic outer surface is also appropriate for the invention. Any type of metal may be coated, but metals such as steel, stainless steel, gold, silver, platinum or titanium are preferred.

The present invention, in a third aspect, provides a coating for a hearing aid component, wherein the coating is produced in a process comprising the steps of:
providing a hearing aid component;
applying an organometallic compound to the surface of the hearing aid component using vapour phase deposition;
inducing a reaction involving the applied organometallic compound to convert it to a metal oxide layer;
applying a silane molecule to the metal oxide on the surface of the hearing aid component using vapour phase deposition; and
   inducing a reaction between the applied silane molecule and the metal oxide to form covalent links between the silane molecules and the metal oxide or to covalently link neighbouring applied silane molecules.

### BRIEF DESCRIPTION OF THE DRAWINGS

The invention will be readily understood from the following detailed description in conjunction with the accompanying drawings. As will be realised, the invention is capable of other different embodiments, and its several details are capable of modification in various, obvious aspects all without departing from the invention. Accordingly, the drawings and descriptions will be regarded as illustrative in nature and not as restrictive. In the drawings:

FIG. 1 illustrates a Behind-The-Ear (BTE) hearing aid with a sound conduit;

FIG. 2 illustrates a Behind-The-Ear hearing aid of the Receiver-In-Canal (RIC) type;

FIG. 3 illustrates an In-the-Ear hearing aid;

FIG. 4 illustrates an earwax guard;

FIG. 5 illustrates mounting of an earwax barrier element and a standard earwax guard in the interior of a hearing aid component;

FIG. 6 illustrates a BTE hearing aid with an FM unit;

FIG. 7 shows a schematic diagram of a typical system for vapour phase deposition.

### DETAILED DESCRIPTION OF THE INVENTION

In order to more fully detail the present invention some of the terms used in the description of embodiments of the invention are explained in the following.

A “component for a hearing aid” may be any individual component used in manufacturing a hearing aid, such as housings, casings, shells, internal electronic circuitry, transducers, faceplates, grids, barriers, hooks, lids, battery compartments, buttons, switches, manipulators, connectors, sound conduits, electrical wires, ear pieces, earwax guards, FM units etc., or the component may also be an assembly of several such components, or even an essentially fully assembled hearing aid. A component may range in complexity from an individual element created from a single material, such as a polymer, a metal, or another appropriate material, to elements comprising several different such materials as well as including mechanical and/or electronic functionalities.

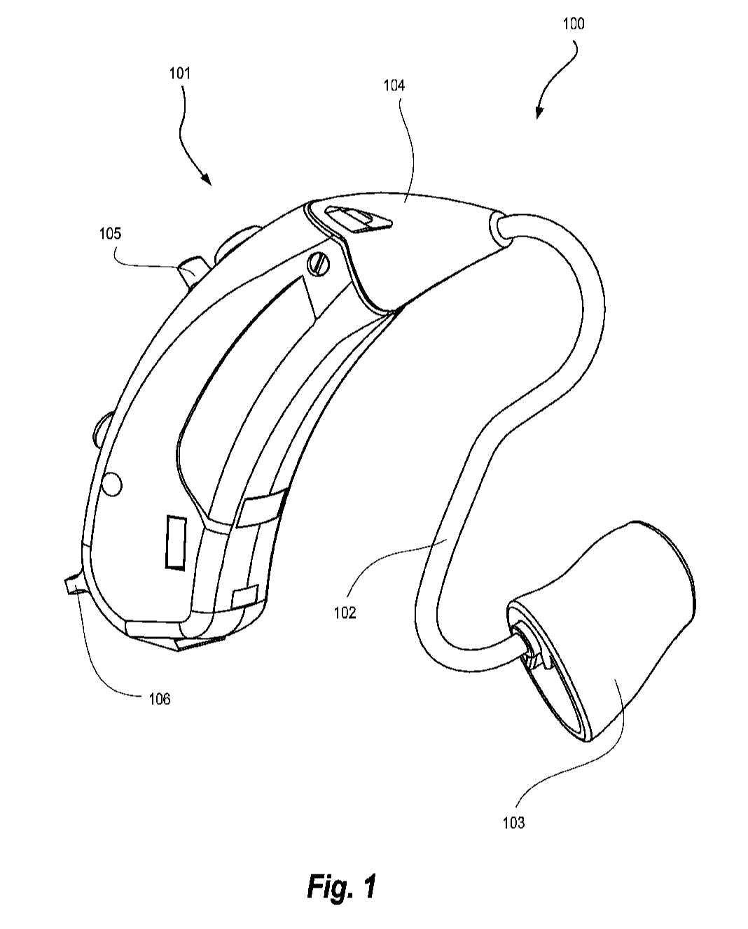

FIG. 1 illustrates a traditional Behind-The-Ear (BTE) hearing aid 100 comprising a variety of components that may be advantageous to coat. These components include at least a BTE housing 101, a sound conduit 102, an ear piece 103, an adaptor hook 104, a volume control 105 and a power switch 106.

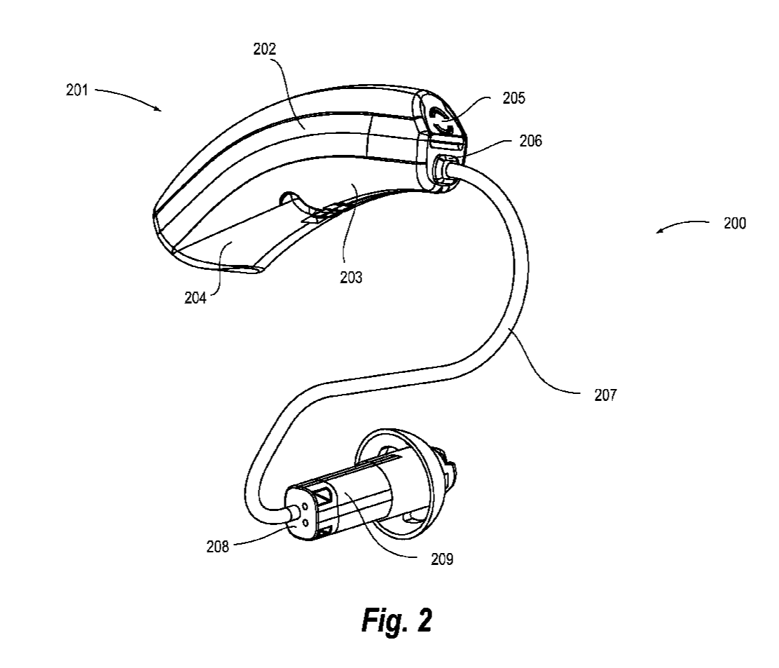

FIG. 2 illustrates a BTE hearing aid of the Receiver-In-Canal (RIC) type 200 comprising a variety of components that may be advantageous to coat. These components include at least a BTE housing 201, an upper housing shell 202, a lower housing shell 203, a battery compartment 204, a microphone grid 205, connecting means 206 providing the electrical connection between the BTE housing 201 and the electrical leads of the wire element 207, and connecting means 208 providing the electrical connection between the RIC housing 209 and the electrical leads of the wire element 207.

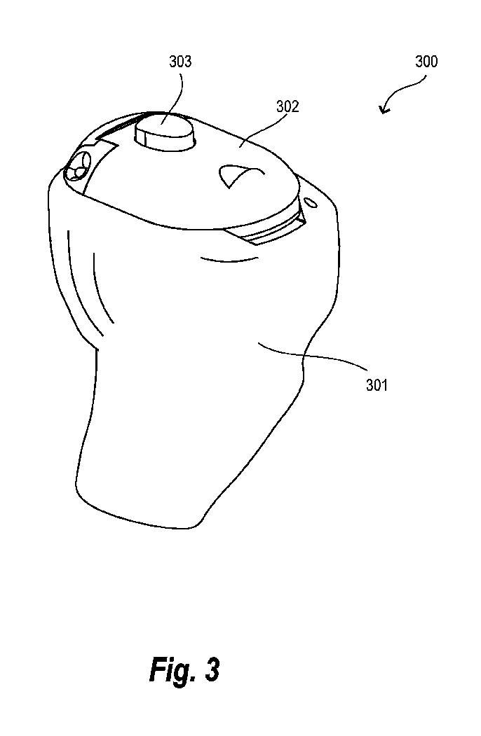

FIG. 3 illustrates an In-The-Ear (ITE) hearing aid 300 comprising a variety of components that may be advantageous to coat. These components include at least an ITE shell 301, a battery lid 302 and a volume control 303.

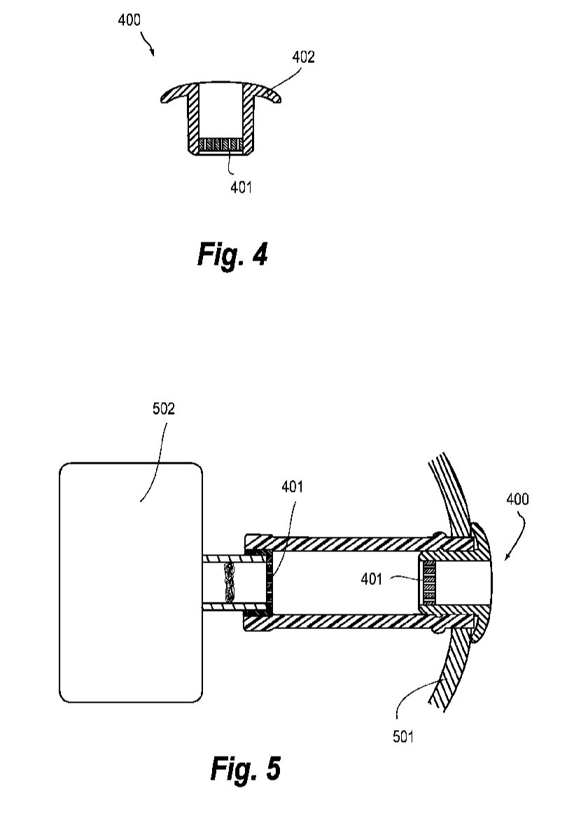

FIG. 4 illustrates an earwax guard 400 comprising an earwax barrier element 401 and a tubular element 402.

FIG. 5 illustrates mounting of both a receiver earwax barrier element 401 and an earwax guard 400 inside a hearing aid component housing 501. The receiver barrier element is mounted on the output pipe of the hearing aid receiver 502.

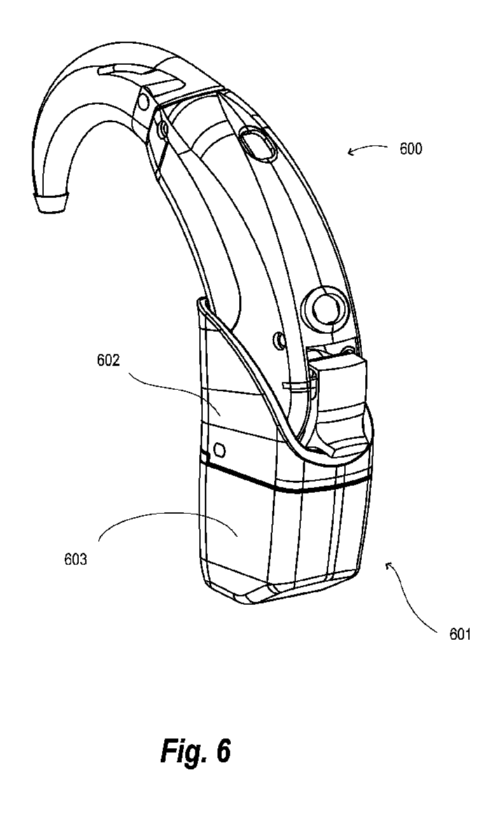

FIG. 6 illustrates a BTE housing 600 comprising an FM shoe 601 that may be advantageous to coat. The FM shoe 601 has an upper part 602 that may adapted for a variety of different hearing aid housings and a lower part 603 that contains the FM unit.

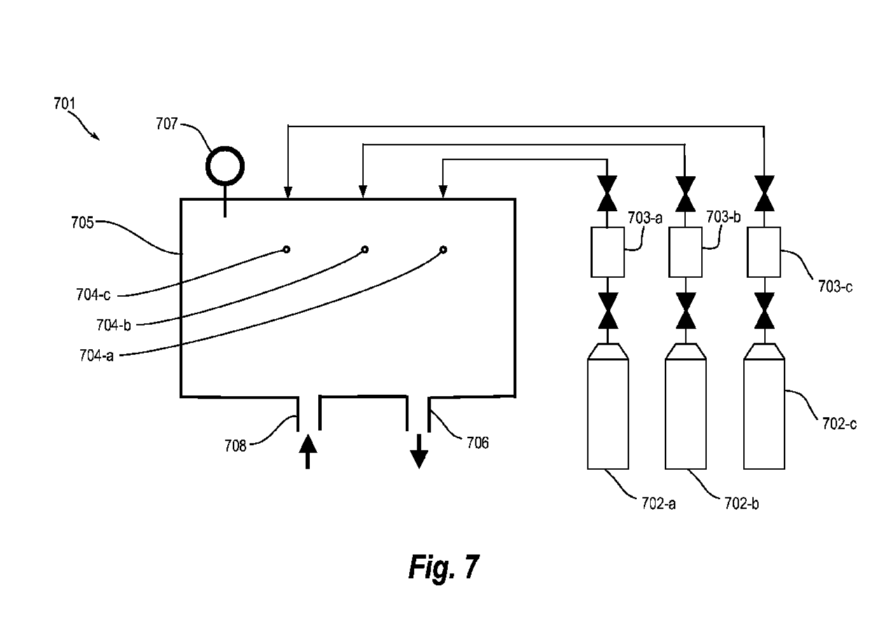

FIG. 7 shows a schematic diagram of a typical system for vapour phase deposition.

The surface of a component for a hearing may also be referred to as a “hearing aid surface”. Thus, a hearing aid surface may be a metallic, plastic, metallised, painted or otherwise coated surface. Some surface materials may advantageously be subjected to a plasma treatment to activate the surface by introducing superficial hydroxyl groups before coating in the vapour phase deposition step. The plasma treatment is particularly important for non-metallic, polymeric substrates.

As used in the context of the present invention, the term “vapour phase deposition” refers to a range of techniques for coating a surface with a layer of molecules. In general, vapour phase deposition comprises a step to deposit molecules of an appropriate reactivity from a vapour phase onto a surface followed by the induction of a reaction to allow the deposited molecules to react with neighbouring deposited molecules and/or with chemical moieties on the substrate surface. The deposited layer may take the form of a molecular monolayer, or the thickness of the layer may correspond to several molecules. One example of a molecular monolayer is a so-called self-assembled monolayer (SAM). Layers with thicknesses of more than one molecular layer may be created by the simultaneous deposition of the layers, or the layers may be created by the sequential deposition of, and subsequent induction of reaction between, several monolayers. Several types of vapour phase deposition methods are known in the art, such as chemical vapour deposition (CVD), atomic layer deposition (ALD), molecular vapour deposition (MVD), vapour phase epitaxy, atomic layer epitaxy etc. In an embodiment the vapour phase deposition of the present invention is the type known as molecular vapour deposition. This molecular vapour deposition may appropriately be performed in an MVD-apparatus, such as an MVD-100, MVD-100E or MVD-150, supplied by Applied Microstructures Inc. (San Jose, Calif., USA). This apparatus is also capable of performing atomic layer depositions to form the metal oxide coating. In yet another embodiment both molecular vapour deposition and atomic layer deposition are applied in the coating step.

By “organometallic compound” is understood a compound comprising a metal atom covalently linked to a carbon atom. For use in the coating of the present invention trimethyl aluminium (TMA or Al(CH₃)₃) is an especially suited organometallic compound, although as will be clear to those skilled in the art several other organometallic compounds may be used. Typical metals found in organometallic compounds include aluminium, gallium, indium, and also transition metals, such as titanium or zinc. In the context of the present invention, compounds comprising semimetallic elements, such as boron, silicon, arsenic, and selenium covalently linked to a carbon atom are also considered organometallic compounds.

The reaction between TMA and hydroxyl on a metal surface may take place according to the following reaction, thus corresponding to step b) in the method to produce the coating of the invention:

Al(CH₃)₃(g)+M-OH(s)→M-O—Al(CH₃)₂(s)+CH₄(g)

The subsequent step c) may then take place according to the following reaction:

2H₂O(g)+M-O—Al(CH₃)₂(s)→M-O—Al(OH)₂+2CH₄(g)

In these reactions “M” denote a metal, “(s)” indicates atoms on the surface of a substrate, and “(g)” refers to a gaseous or vapour phase.

The layer thickness of the aluminium oxide layer thus produced will be approximately 1 Å.

According to an embodiment of the invention the organometallic compound is TMA (Al(CH₃)₃). TMA has been found to be especially advantageous compared to using e.g. tetrachlorosilane (SiCl₄) as a precursor, which has commonly been employed in the prior art. Tetrachlorosilane is well known for producing layers of silicon oxide on substrates. Such processes typically involve vapour phase deposition of the silane on the substrate followed by a reaction to convert the adsorbed layer to the oxide. However, this process involves the formation of hydrogen chloride (HCl) as a reaction product, which is known to be highly corrosive. The corrosivity of HCl is problematic both for the coated substrate, the coating itself and to the environment in which the reaction is performed. In contrast, reacting adsorbed TMA with water to form an aluminium oxide layer as is done in the present invention will result in the formation of methane (CH₄). In comparison to HCl, methane is practically inert and its formation will not cause any problems related to corrosion.

The term “precursor” as used throughout this document generally refers to molecules or compounds taking part in chemical reactions. Thus, TMA, water, silanes etc. may all be considered precursors, although the term is not limited to these compounds.

It has furthermore been found that a layer of aluminium oxide formed on a surface in a coating of the present invention provides improved adhesion between the outermost coating and the substrate. In the present invention the metal oxide layer formed between the surface of the hearing aid component substrate and the silane layer on the exterior surface may therefore also be described as an “adhesion layer”. This means that the metal oxide layer serves to enhance the strength of binding of the silane layer to the hearing aid component, compared to a situation where the silane layer was applied directly to the hearing aid component. Without being bound by any particular theory it thus appears that by employing a metal oxide adhesion layer, such as aluminium oxide, the durability and mechanical stability of the hearing aid component, and therefore of the hearing aid, will also be improved.

Without being bound by theory, it is speculated that this improved adhesion additionally improves the general mechanical properties of the coated substrate, so that this will become more resistant to scratching and similar physical challenges.

In the present invention the term “silane molecule” describes a compound, which may be represented with the general formula: R₄Si, where R may be the same or different chemical moieties.

In some embodiments the silane molecule may be denoted as (R¹)₃SiR², wherein R¹ are moieties capable of forming covalent links with neighbouring silane molecules or hydroxyls present in a metal oxide under appropriate conditions, and R² is an alkyl chain, which may comprise any desired functional group or groups. In some embodiments R¹ is chlorine, methoxy or ethoxy.

The functional groups of the alkyl chain R² may serve to make the coating hydrophobic, hydrophilic, positively charged, negatively charged or to provide chemically reactive groups. Hydrophobic alkyl chains may for example be underivatised alkyls, or they may be perfluoroalkyl chains. Hydrophilic functionality may be provided from hydroxyl groups on R². If charged functionalities are desired, negative charges may be obtained from carboxylate or sulfonate groups, and positive charges from primary, secondary, tertiary or quaternary amines attached to R². Reactive groups may be epoxies, such as glycidyl moieties. It may however be necessary to supply the functional group or groups of the alkyl chain R² with protective groups in order to prevent or minimise unwanted polymerisation of the silane molecules. This is especially relevant in case it is aimed to introduce hydrophilic or charged moieties. The use of such silane molecules with protective groups is also contemplated in the present invention. Alternatively, such functionalities may also be attached by first reacting with a silane molecule carrying a reactive group, such as a glycidyl or epoxy, and then reacting this group with an appropriate reagent to introduce the desired functionality. Epoxy-carrying alkyl chains may for example be reacted with nucleophiles, such as amines, sulphite, alcohols, water, hydroxyls, thiols etc. under appropriate conditions, which will be well-known to those skilled in the art.

In an embodiment the silane molecule is derivatised with a perfluoroalkyl chain. In yet another embodiment the silane molecule is perfluorodecyl trichlorosilane (FDTS). Perfluoro derivatised silanes serve to make the surface of the hearing aid component hydrophobic or superhydrophobic as explained below.

The silane molecule may also carry only one or two R¹-moieties (in addition to the R²-moiety) so that the molecule may be represented by the general formulas: R¹(R³)₂SiR², (R¹)₂R³SiR², where R³ represents an essentially inert group, such as an alkyl-chain.

“Superhydrophobicity” is used to describe a material property where a drop of water will slide or roll off a “superhydrophobic” surface. The property may be more precisely characterised by the contact angle between the water droplet and the surface. Thus, one quantitative measure of the wetting of a solid by a liquid is the contact angle, which is defined geometrically as the internal angle formed by a liquid at the three-phase boundary where the liquid, gas and solid intersect. Contact angle values below 90° indicate that the liquid spreads out over the solid surface in which case the liquid is said to wet the solid (this may be termed “hydrophilic”). If the contact angle is greater than 90° the liquid instead tends to form droplets on the solid surface and is said to exhibit a non-wetting (or “hydrophobic”) behaviour.

In this terminology it follows that the larger the contact angle, the better the ability of a surface to repel a respective substance. For untreated surfaces the contact angle is normally less than 90°. It is well known in the art to coat a solid with a hydrophobic layer in order to increase the contact angle and thereby obtain a moisture repellent surface. Such a surface coating may typically increase the contact angle of water to around 115-120°. A structural modification, such as microstructuring, of the surface of certain materials will improve the ability of the material to repel aqueous and oily substances. When the surface is modified by a combination of such structuring and a (hydrophobic) coating, the contact angle of water exceeds 145° for a variety of materials, and this characteristic is termed superhydrophobic in the context of this invention. In addition to the superhydrophobic surface characteristics, the modified materials may also obtain superoleophobic surface characteristics.

In one embodiment of the invention a hearing aid component with a microstructured surface is provided with a coating embodying the invention thus making the coated hearing aid component superhydrophobic.

The surface structuring is preferably realised on lateral scales that are much larger than characteristic sizes for atoms and molecules as well as for grains or other sub-nanometer structures, but not larger than 100 microns. This is referred to as a “microstructure”.

The structuring and/or coating can be applied to the entire component surface or it can be applied to a part of it. A controlled structuring of at least a part of the surface in the immediate vicinity of any pores in the component may be particularly advantageous.

The applied microstructure can be periodic, quasi-periodic or random within a certain spatial bandwidth. The spatial bandwidth is defined as the range of reciprocal wave numbers of the lateral scales of the structure, the wave number being defined as the reciprocal value of the lateral wavelength of a periodic structure. The structure is applied to at least a part of the component surface. The average pitch in the surface structure should be 100 microns or lower. The aspect ratio is typically about 1:1 or larger. Good results have been obtained with samples over a broad pitch range, including pitch at 40 microns, 10 microns and 5 microns.

The surface structuring may be performed by a number of methods, for example by laser processing of the surface with thermal or non-thermal interactions. Non-limiting examples of lasers that can be used for surface structuring are CO₂ lasers, excimer lasers, diode lasers, fibre lasers, solid state lasers, such as Nd:YAG, picosecond lasers and femtosecond lasers. Processes used in the fabrication of micro/nano-electronics or micro/nano-electromechanical systems as well as other etching or electrochemical processes can also be applied.

For a number of components of the hearing aid, e.g. housings, casings, shells, faceplates, grids, hooks, lids, battery drawers, buttons and manipulators, it is generally preferred to manufacture them by injection moulding. In this case structuring of the component surface may be achieved through suitable structuring of an inner surface of the die used, e.g. by laser drilling, etching, or spark treatment. In case of components manufactured by an SLA technique, sometimes referred to as a rapid prototyping method, it is generally preferred to provide microstructuring of the component surface subsequent to the moulding, e.g. by laser processing, etching or electrochemical processing. As an alternative the microstructured component may also be prepared in a microinjection moulding step or using hot embossing principles.

The same technologies for providing a microstructure to the surface of a hearing aid component may generally also be employed when it is relevant to provide the hearing aid component with a number of through-going pores. Such pores will generally have a largest cross-sectional dimension of 100-200 μm. In this context, the cross-section refers to the cross-section of the pore seen from the surface of the perforated substrate. The shape of this cross-section may be circular, ellipsoidal, or polygonal etc., and when the cross-section has a circular shape, the largest cross-sectional dimension corresponds to the diameter. The shape of the cross-section will commonly be dependent on the method employed for its provision. For example, laser ablation will often yield generally circular pores, whereas stamping may provide pores of other shapes dependent on the stamp employed. Through-going pores will be of importance to hearing aid components of a limited thickness, such as less than a millimetre. These components may serve as filters to prevent penetration of earwax, dust or the like. The acoustic properties of a component with through-going pores may be of importance, so that the sizes and shapes of the pores as well as the lattice of the pores provided to the component may be considered prior to providing the pores. The depth-wise shape of the pores is not particularly limited. Thus, the shape and cross-sectional dimensions of through-going pores may be approximately the same on both sides of the hearing aid component, or the cross-sectional dimensions may be of different sizes, so that a pore is smaller seen from one side of the surface than from the other. Likewise, the pore may be, e.g., circular on one side and approximately ellipsoidal on the other.

A typical system for vapour phase deposition of precursors for producing a coating embodying the invention is illustrated schematically in FIG. 7. The system 701 comprises a reservoir 702a-c for each precursor, which in the illustrated embodiment will be water, TMA and FDTS. Each reservoir is in fluid communication with an evaporation chamber 703a-c via a conduit comprising a valve. The evaporation chambers 703a-c are each in fluid communication with a gas injection port 704a-c for injecting the precursor into a reaction chamber 705; the conduits between the evaporation chambers 703a-c and the reaction chamber 705 may comprise valves, and the conduits are preferably heated in order to avoid condensation of the evaporated precursors. The reservoirs 702a-c and the evaporation chambers 703a-c may also be heated. The reaction chamber 705 will be temperature controlled and in fluid communication with a vacuum pump 706 allowing the pressure in the reaction chamber 705 to be controlled. In the following the unit “Torr” will be used for pressure; 1 Torr corresponds to around 133 Pa. Both pressure and temperature in the reaction chamber 705 will depend on the specific precursors applied to the chamber, but the pressure will typically be from 0.01-10 Torr, and the temperature will be from ambient temperature to 100° C., typically between 35 and 60° C. The temperature may, however, also be increased above this range (to e.g. 150° C.) and will also be dependent on the nature of the substrate. For example, when polymer materials are coated the reaction conditions should take into consideration the nature of the polymer to avoid softening or melting of the polymer. In certain cases it may be desirable to decrease the pressure even below 0.01 Torr. The system 701 may be equipped with a sensor 707 to monitor the temperature and pressure and other conditions inside the reaction chamber 705, as appropriate for a given reaction. Furthermore, the system may also be appropriately designed to include a supply (not shown) for a purging gas, e.g. N₂, to include a purging step between applications of precursors.

For substrates, such as polymeric materials, where a plasma treatment is appropriate, the system 701 may comprise a plasma source 708 for treating the substrate surfaces. Oxygen (O₂) plasmas are typically employed when application of a plasma is appropriate. The plasma treatment is suited for both cleaning and activation of certain substrates, and may therefore also be included when processing materials other than polymers.

The system 701 will be equipped with appropriate access ports (not shown) for placing substrates in the reaction chamber 705 and removing them after the completion of the reaction. Likewise, the reaction chamber will be fitted with racks, shelves or the like (not shown) for holding the substrates during the reactions.

Following positioning of a substrate in the reaction chamber 705 pressure and temperature in the chamber 705 will be set as appropriate, and the reservoirs 702 may be heated. In general, the reaction chamber 705 will be evacuated using the vacuum pump 706 before allowing a reactant into the chamber thereby controlling the pressure. The relevant precursor, e.g. TMA, is then vaporised from its reservoir into the evaporation chamber by opening the valve between reservoir 702 and evaporation chamber 703. When a specified pressure is reached, the valve is closed, and the precursor in the evaporation chamber 703 is then injected into the reaction chamber 705 via the gas injection port 704 by opening the valve between evaporation chamber 703 and reaction chamber 705. Once pressure equilibrium between the two chambers has been reached, the valve between them is closed. A given precursor can be injected a number of times into the reaction chamber 705, as long as the pressure in the evaporation chamber 703 is larger than in the reaction chamber 705. More than one precursor may also be applied into the reaction chamber 705 at the same time, depending on the specific reaction to be performed. Following introduction of the precursor into the reaction chamber 705, the precursor will be allowed to react for a specified period of time. The reaction may be an adsorption onto the substrate, or the introduction of a precursor may induce a reaction on the substrate surface. Certain precursors may react spontaneously when adsorbed on the substrate surface. After the specified reaction time, any precursors and by-products are pumped out of the reaction chamber 705 using the vacuum pump 706. This evacuation may be followed by a number of purge steps employing an inert gas, such as nitrogen.

In one embodiment, TMA and water are applied at 0.01-10 Torr for 0.1-60 s, or even more preferred for 0.5-10 s, and FDTS is applied at 0.01-10 Torr, more preferred below 1 Torr, for 1-60 min, more preferred for 5-30 min. In case 1,2-bis(trichlorosilyl)ethane is employed the pressure will typically be between 0.01-10 Torr, preferably below 2 Torr.

In a different embodiment, the system comprises reservoirs containing the precursors, a reaction chamber and conduits for the precursors constructed to allow a constant flow of gaseous precursors through the reaction chamber. Reservoirs, evaporation chambers and reaction chamber may be heated and the gas flow rates can be adjusted. The conduits for the reservoirs may comprise valves for separating the reservoirs from the conduits. A plasma source for cleaning and activation of the surfaces may be an integrated part of this system. Each precursor is vaporised from the reservoir into the gas line by opening the valve between reservoir and gas line for a specified time, after which time the valve is closed. In this setup, the purge time is defined as the time where no precursor is injected into the gas flow. When operating with two different precursors A and B, a possible process order may be as follows: Injection of precursor A, purge, injection of precursor B, purge. The time for injection of the precursors and the purge times may be the same or different, and will typically appropriately be measured in seconds. This process order (denoted a cycle) may be repeated any number of times. The important parameters in this type of operation are, in addition to the purge and injection times, the interplay between the purge and injection times as well as the gas flow rate.

### EXAMPLES

The invention will now be described in the non-limiting Examples outlined below. For comparison an Example of the prior art technique is also given. The Examples illustrate specific embodiments of the invention, and are not intended to limit the invention.

### Prior Art Example

As an illustration of the prior art techniques four different polymer types, ABS, PA, PE and POM, were coated with an adhesion layer of silicon oxide followed by an outer layer of FDTS. Centimetre sized specimens of the polymers were initially subjected to an oxygen plasma treatment, and then vapour phase deposition of SiCl₄ was performed in an MVD-apparatus (MVD-100 from Applied Microstructures, Inc., San Jose, Calif., USA) followed by reaction with water vapour to induce polymerisation and formation of silicon oxide. FDTS was then applied in the MVD-apparatus to introduce a hydrophobic outer layer.

The coated samples were heated overnight at 65° C. before exposure to artificial sweat. The sweat test was conducted in a desiccator at 65° C. where the coated specimens were exposed to an artificial sweat composition (Microtronic) of pH 3 for up to 10 days. Samples were removed from the desiccator after 1, 3, 5, 7 and 10 days, and static contact angles of water droplets applied to the samples were recorded; four measurements were obtained for each sample.

The results are summarised in Table 1 below, where the mean values of the contact angles are given with their respective 95% confidence intervals as calculated from the measurements.

TABLE 1
hydrophobic coatings of the prior art

| Exposure | | | | |
|---|---|---|---|---|
| time | ABS | PA | PE | POM |
| 1 day | 103.1 ± 2.4° | 100.2 ± 5.2° | 107.4 ± 0.8° | 98.6 ± 4.5° |
| 3 days | 37.7°/107.3°* | 105.0 ± 1.1° | 107.4 ± 1.9° | 106.9 ± 0.7° |
| 5 days | 36.8°/108.1°* | 105.4 ± 0.2° | 108.0 ± 0.7° | 107.2 ± 0.6° |
| 7 days | 47.3 ± 8.5° | 105.4 ± 0.8° | 104.5 ± 1.9° | 104.4 ± 1.2° |
| 10 days | 56.1 ± 4.3° | 105.8 ± 0.9° | 106.8 ± 0.8° | 29.7 ± 15.3° |

*Two of the four droplets applied collapsed quickly after application resulting in the lower contact angles; confidence intervals were not calculated in these instances.

The results indicate that for ABS and POM this prior art method did not result in stable coatings. For ABS half of the applied droplets “collapsed” on the plastic surface of samples subjected to only three days of exposure to the artificial sweat. With “collapsed” is meant that the individual droplets initially had a high contact angle with the surface but then started spreading over the surface giving rise to a much lower contact angle (i.e. showing a wetting behaviour). After 7 and 10 days of sweat testing all applied droplets collapsed briefly after application. The droplets further left visible marks in the polymer material.

The POM material exhibited somewhat different characteristics. The measured contact angles were generally high, showing a hydrophobic surface, although the contact angles tended to decrease gradually. For example, droplets applied to the 7-day sample had contact angles as shown in Table 1, but after standing for approximately 90 minutes the values decreased to 83.7±4.7°. Moreover, the droplets left visible marks on the surface. For the 10-day sample the droplets collapsed within seconds of application and left very visible marks. Close inspection of this sample indicated that material tended to “peel off” from the surface.

The PA and PE samples showed more stable results. In these cases the droplets did not collapse, but only showed a small decrease in contact angle as shown by remeasuring the angles after approximately 90 minutes of standing. Thus, for PA the value for the 7-day sample decreased to 97.6±0.3°, and for the 10-day sample to 94.3±2.0°. For PE the respective values were 93.1±1.6° and 89.9±2.7°.

The differences observed between the polymer types may partly be explained by differences occurring from the plasma treatment. The PE and PA employed are chemically closely related, and the similar results observed for these two types may indicate that the plasma treatment introduces different amounts of reactive hydroxyl groups for different polymer types, making the prior art method more suited for e.g. PE and PA than for ABS and POM.

For the production of hearing aids and components for hearing aids ABS and POM are more relevant materials than either of PE or PA. Thus, the results show that an improved method for coating of hearing aid components is needed.

### Example 1

An exemplary coating embodying to the invention was produced using the MVD-100. This system had a reaction chamber of an approximately square footprint with a 150 mm length and width and 30 mm height and three independent precursor reservoirs and corresponding connections to the reaction chamber. It is further equipped with an oxygen plasma supply. The volume of each evaporation chamber is 300 mL.

For the coating reaction 200 hearing aid components made from Acrylonitrile Butadiene Styrene (ABS) were placed in the reaction chamber. Different types of components were coated, and each component had a surface area of 5-10 cm². An oxygen plasma was then applied at 250 W and 200 sccm O₂ (standard cubic centimetres per minute) with a 5 min treatment time. Following the plasma treatment, 40 cycles of aluminium oxide coating were performed by first applying TMA, then reacting the adsorbed TMA with water. In the following, the indicated pressures are for the evaporation chambers. In each cycle TMA at 4 Torr and ambient temperature was deposited on the substrate for 1 s followed by a single purge with nitrogen gas. Conversion of the adsorbed TMA to a covalently linked layer of aluminium oxide was subsequently provided by applying water vapour at 0.8 Torr and 50° C. and allowing a reaction time of 1 s, followed by 5 purges.

After coating the hearing aid components with the aluminium oxide adhesion layer, the component surfaces were made hydrophobic by application of FDTS followed by water vapour to react the FDTS with the hydroxyls on the component surfaces. Specifically, FDTS was applied in four steps with each step performed at 0.5 Torr and 55° C., and the fourth FDTS-application step was followed by application of water vapour at 18 Torr and 50° C. A reaction time of 15 min was then employed to react the water molecules with the FDTS-molecules. Finally, the reaction chamber was purged five times with nitrogen gas.

The deposition was carried out at a reaction chamber temperature of 60° C.

The hydrophobic and oleophobic properties of the coated hearing aid components were analysed by measuring contact angles between the surfaces and water and olive oil, respectively. Water and olive oil serve as models for sweat and earwax, respectively, which are common causes for deterioration of hearing aid performance. Static contact angles of approximately 110-115° were observed for water, and angles of approximately 80-85° for olive oil.

The coating procedure was repeated with hearing aid components with a microstructured surface. The final FDTS-coated, microstructured hearing aid components displayed improved hydrophobic and oleophobic properties over the coated components not having a microstructured surface, as static contact angles of about 150° for water and about 130° for olive oil were observed. Thus, the surfaces were made both superhydrophobic and superoleophobic by the coating procedure.

The reaction between water and silane led to formation of covalent links between aluminium oxides and the silane (i.e. Al—O—Si-links) as well as a limited polymerisation between adsorbed silanes (i.e. Si—O—Si-links). The use of TMA to produce an adhesion layer creates a mechanically more robust coating than afforded by the more traditional coating process employing SiCl₄ instead of TMA. When SiCl₄ is used to create a layer of silicon dioxide on the surface, HCl is released upon reaction with hydroxyls and water. HCl is corrosive, and it is suspected that the corrosive effect may lead to a sub-optimal reaction. In particular, the HCl formed may be damaging to electronic circuitry in the substrate. In contrast, adsorption of TMA to the surface and reaction with hydroxyls and water will lead to formation of methane, which compared to HCl, is completely inert. Without being bound by any particular theory it is believed that coatings embodying to the invention are mechanically more robust compared to the prior art partly due to it that the TMA may interact with the uppermost surface of polymers. Thereby an Al₂O₃-layer may be formed which is mechanically embedded in the polymer, or there may possibly also be formed a hybrid organic/inorganic layer, since the plasma activation results in the formation of reactive hydroxyls on the polymer.

### Example 2

POM microphone grids were coated with hydrophobic top layers of FDTS in the following combinations:
Aluminium oxide+FDTS
Aluminium oxide+silicon oxide+FDTS
Silicon oxide+FDTS with two different thicknesses of the silicon oxide layer

Aluminium oxide layers were prepared by deposition of TMA followed by reaction with water at a deposition temperature of 60° C. in an ALD process. Silicon oxide layers were prepared by deposition of 1,2-bis(trichlorosilyl)ethane followed by reaction with water at a deposition temperature of 35° C. in an MVD process. Subsequent coatings with FDTS were performed at 35° C. also in a vapour phase deposition process.

The coated components were exposed to artificial sweat in a test to mimic conditions of use of a hearing aid. The conditions comprised storing the components for 24 hours in warm water mixed with NaCl and acetic acid. This ageing test emulates the degrading influence of sweat. Before and after the test contact angles between water droplets and the coated components were analysed. Several analyses were performed for each component. The results of the analyses are summarised in Table 2.

TABLE 2
coating of microphone grids

| | Contact angle with | Contact angle with |
|---|---|---|
| Coating | water prior to sweat test | water after sweat test |
| Aluminium oxide + | 127.5 ± 1.0° | 124.3 ± 2.5° |
| FDTS | | |
| Aluminium oxide + | 125.1 ± 1.6° | 124.1 ± 2.5° |
| Silicon oxide + FDTS | | |
| Silicon oxide + FDTS | 128.2 ± 2.5° | 121.0 ± 3.1° |
| (low layer thickness) | | |
| Silicon oxide + FDTS | 130.7 ± 2.1° | 125.2 ± 2.8° |
| (high layer thickness) | | |

As seen from Table 2, the method of present invention provided excellent durability to the hydrophobic coatings. Application of a step to provide an aluminium oxide adhesion layer provided an even better result than coating methods not employing TMA. Thus, as seen from the results there was no statistical difference between contact angles for substrates with a coating comprising aluminium oxide before and after exposure to the sweat test, whereas for coatings without the aluminium oxide layer the contact angles decreased after exposure to the sweat test.

### Example 3

Filters were prepared from a submillimetre thickness sheet of steel containing a lattice of through-going holes. The filters prepared were of sizes typically used in hearing aids with a pattern of holes and hole diameters (190 μm) intended to prevent penetration of earwax through the filters. The following three coating types were then applied to the filters:
Aluminium oxide+FDTS
Aluminium oxide+silicon oxide+FDTS
Silicon oxide+FDTS

The coating procedures were as explained above in Example 2. For comparison a section of the sheet without holes was also coated with silicon oxide and FDTS. Hexadecane was used as a hydrophobic model compound, and the contact angles between hexadecane and the coated substrates were measured. Several analyses were conducted for each substrate. Furthermore, penetration of olive oil through the filters was analysed by placing 15 droplets of oil on the upper surface of each of three sheets with filters and recording the penetration. The sheets with droplets of olive oil were retained at a generally horizontal orientation for at least 14 weeks.

The results of the contact angle measurements are summarised in Table 3.

TABLE 3
coating of earwax filters

| Coating | Hexadecane contact angle |
|---|---|
| Aluminium oxide + FDTS | 116.8 ± 1.4° |
| Aluminium oxide + silicon oxide + FDTS | 117.8 ± 0.6° |
| Silicon oxide + FDTS | 113.5 ± 0.9° |
| Sheet with silicon oxide + FDTS | 75-80° |

As evident from Table 3, all three coated filters had markedly larger contact angles than the steel sheet with a top layer of FDTS but without any holes through the sheet. Thus, the combination of an FDTS top layer and the structuring resulting from the lattice of holes provided an oleophobic surface.

The oleophobic filters were tested for penetration of olive oil. After 14 weeks no droplets had crossed the filter coated with aluminium oxide+FDTS, whereas one droplet had migrated through the filter with a coating of aluminium oxide+silicon oxide+FDTS after 9 weeks. For the filter without an aluminium oxide adhesion layer two droplets had penetrated the filter after only 4 hours and a further droplet after 14 days; no additional droplets had crossed the filter after 8 weeks. The fast initial penetration of oil through the silicon oxide+FDTS coated filter in comparison with the filters comprising an aluminium oxide layer may reflect a defect in the filter existing prior to the coating. This is supported by the fact that no further droplets crossed the filter in the following weeks. However, other causes cannot be ruled out and it may be an indication that the aluminium oxide layer for the other two filters provides a more robust coating.

1. A method for coating a hearing aid component, the method comprising the steps of:
providing a hearing aid component;
a) applying an organometallic compound to the surface of the hearing aid component using vapour phase deposition;
b) inducing a reaction involving the applied organometallic compound to convert it to a metal oxide layer;
c) applying a silane molecule to the metal oxide on the surface of the hearing aid component using vapour phase deposition; and
d) inducing a reaction between the applied silane molecule and the metal oxide to form covalent links between the silane molecule and the metal oxide or to covalently link neighbouring applied silane molecules.

2. The method according to claim 1, wherein the organometallic compound is trimethyl aluminium (Al(CH₃)₃).

3. The method according to claim 1, wherein the silane molecule comprises a perfluoroalkyl moiety.

4. The method according to claim 1, wherein the steps b) and c) are repeated to provide a desired thickness of the metal oxide layer

5. The method according to claim 4, wherein in each repeated step b) the organometallic compound applied may be the same as that applied in the preceding step b) or the organometallic compound may comprise a different metal than that applied in the preceding step b).

6. The method according to claim 1, wherein the thickness of the metal oxide layer is between 2 nm and 20 nm.

7. The method according to claim 1 comprising a step of treating the surface of the hearing aid component with an oxygen plasma prior to applying an organometallic compound.

8. The method according to claim 1 comprising a step of microstructuring the exterior surface of the hearing aid component prior to applying the organometallic compound.

9. The method according to claim 1 comprising a step of perforating the hearing aid component with a number of through-going pores, the largest cross-sectional dimension of each of the pores being smaller than 200 μm, prior to applying the organometallic compound.

10. A hearing aid comprising a component provided with a hydrophobic coating comprising a layer of aluminium oxide.

11. The hearing aid according to claim 10, wherein said component comprises a microstructured outer surface.

12. The hearing aid according to claim 10, wherein said component comprises a number of through-going pores, the largest cross-sectional dimension of each of the pores being smaller than 200 μm.

13. The hearing aid according to claim 10, wherein said component comprises an outer surface of a polymeric material.

14. The hearing aid according to claim 13, wherein the polymeric material is selected from a group comprising polyoxymethylene (POM), acrylonitrile butadiene styrene (ABS), and acrylonitrile butadiene styrene/polycarbonate (ABS/PC).

15. The hearing aid according to claim 10, wherein said component comprises an outer surface of a metallic material.

16. The hearing aid according to claim 17, where the metallic material is steel.

17. A coating for a hearing aid component, wherein the coating is produced in a process comprising the steps of:
providing a hearing aid component;
applying an organometallic compound to the surface of the hearing aid component using vapour phase deposition;
inducing a reaction involving the applied organometallic compound to convert it to a metal oxide layer;
applying a silane molecule to the metal oxide on the surface of the hearing aid component using vapour phase deposition; and
inducing a reaction between the applied silane molecule and the metal oxide to form covalent links between the silane molecules and the metal oxide or to covalently link neighbouring applied silane molecules.

18. The coating according to claim 17, wherein the organometallic compound is trimethyl aluminium (Al(CH₃)₃).

19. The coating according to claim 17, wherein the silane molecule comprises a perfluoroalkyl moiety.

20. The coating according to claim 17, wherein the steps b) and c) are repeated to provide a desired thickness of the metal oxide layer
